(19) United States
(12) Patent Application Publication
(10) Pub. No.: US 2026/0020308 A1
(43) Pub. Date: Jan. 15, 2026

(54) SEMICONDUCTOR STRUCTURE AND METHOD FOR FORMING THE SAME

(71) Applicant: United Microelectronics Corp., Hsinchu (TW)

(72) Inventor: Chia-Ling Wang, Tainan City (TW)

(73) Assignee: United Microelectronics Corp., Hsinchu (TW)

(21) Appl. No.: 18/796,249

(22) Filed: Aug. 6, 2024

(30) Foreign Application Priority Data
Jul. 11, 2024 (TW) 113125957

(51) Int. Cl. H01L 29/66; H01L 21/8234; H01L 27/088; H01L 29/08

(52) U.S. Cl. CPC H10D 64/021; H10D 62/151; H10D 84/0147; H10D 84/038; H10D 84/83

(57) ABSTRACT

A semiconductor structure and a method for forming the same are provided. The semiconductor structure includes a substrate, a gate structure disposed on the substrate, and a source/drain disposed in the substrate at opposite sides of the gate structure. The gate structure includes a gate dielectric layer disposed on the substrate, a gate electrode disposed on the gate dielectric layer, first gate spacers disposed on opposite sidewalls of the gate electrode, and second gate spacers disposed on the first gate spacers. The first gate spacer each include a first spacer layer on the sidewall, a second spacer layer on the first spacer layer, and a third spacer layer on the second spacer layer. The second spacer layer and the third spacer layer each include a first portion extending along the sidewall and a second portion extending in a direction from the gate electrode to the source/drain.

### CROSS-REFERENCE TO RELATED APPLICATION

This application claims the priority benefit of Taiwan application serial no. 113125957, filed on Jul. 11, 2024. The entirety of the above-mentioned patent application is hereby incorporated by reference herein and made a part of this specification.

### BACKGROUND

### Technical Field

The disclosure relates to a semiconductor structure and a method for forming the same.

### Description of Related Art

As electronic devices are designed toward miniaturization and in the case where

performance requirements for the electronic devices by users are gradually increasing, metal oxide semiconductors (MOS) applied to high-voltage semiconductor elements are more and more severely affected by hot carrier injection (HCI), causing the conventional electronic devices to be insufficient to meet current or future-expected requirements.

### SUMMARY

The disclosure provides a semiconductor structure and a method for forming the same, in which a second spacer layer and a third spacer layer included in a gate spacer each have a portion extending in a direction from a gate electrode to a source/drain, so leakage current caused by hot carrier injection (HCI) can be reduced by increasing the width of the gate spacer.

An embodiment of the disclosure provides a semiconductor structure, which includes a substrate, a gate structure disposed on the substrate, and a source/drain disposed in the substrate at opposite sides of the gate structure. The gate structure includes a gate dielectric layer disposed on the substrate, a gate electrode disposed on the gate dielectric layer, first gate spacers disposed on opposite sidewalls of the gate electrode, and second gate spacers disposed on the first gate spacers. The first gate spacers each include a first spacer layer on the sidewall of the gate electrode, a second spacer layer on the first spacer layer, and a third spacer layer on the second spacer layer. The second spacer layer and the third spacer layer each include a first portion extending along the sidewall of the gate electrode and a second portion extending in a direction from the gate electrode to the source/drain.

In some embodiments, a thickness of the first portion of the second spacer layer is approximately equal to a thickness of the second portion of the second spacer layer.

In some embodiments, a thickness of the first portion of the third spacer layer is approximately equal to a thickness of the second portion of the third spacer layer.

In some embodiments, the gate dielectric layer includes a first portion below the gate electrode and a second portion below the second portion of each of the second spacer layer and the third spacer layer.

In some embodiments, a thickness of the first portion of the gate dielectric layer is greater than a thickness of the second portion of the gate dielectric layer.

In some embodiments, the second gate spacer includes a fourth spacer layer disposed on the third spacer layer and a fifth spacer layer disposed on the fourth spacer layer. The fourth spacer layer includes a first portion extending along the sidewall of the gate electrode and a second portion extending in the direction from the gate electrode to the source/drain.

In some embodiments, a thickness of the first portion of the fourth spacer layer is approximately equal to a thickness of the second portion of the fourth spacer layer, and the fifth spacer layer includes a portion with a thickness changing along a direction perpendicular to a surface of the substrate.

In some embodiments, a bottom surface of the fifth spacer layer is disposed at a level higher than a top surface of the gate dielectric layer.

In some embodiments, a side surface of the fifth spacer layer away from the gate electrode includes a first profile and a second profile different from the first profile.

In some embodiments, relative to a surface of the substrate, the first profile is positioned above the second profile and has a slope less than a slope of the second profile.

In some embodiments, materials of the first spacer layer, the second spacer layer, and the fifth spacer layer include nitride, and materials of the third spacer layer and the fourth spacer layer include oxide.

In some embodiments, the material of the first spacer layer is different from the materials of the second spacer layer and the fifth spacer layer.

An embodiment of the disclosure provides a method for forming a semiconductor structure, which includes the following steps. A gate dielectric layer is formed on a substrate. A gate electrode is formed on the gate dielectric layer. A first spacer layer is formed on opposite sidewalls of the gate electrode. A second spacer material layer covering the gate dielectric layer, the first spacer layer, and the gate electrode is formed above the substrate. A third spacer material layer is formed on the second spacer material layer. A second gate spacer material layer is formed on the third spacer material layer. A portion of the second gate spacer material layer is removed to form second gate spacers above the opposite sidewalls of the gate electrode. A portion of the third spacer material layer and the second spacer material layer is removed to respectively form the third spacer layer and the second spacer layer on the first spacer layer. A source/drain is formed in the substrate at opposite sides of the gate electrode. The second spacer layer and the third spacer layer each include a first portion extending along the sidewall of the gate electrode and a second portion extending in a direction from the gate electrode to the source/drain.

In some embodiments, the substrate includes a first region on which the gate dielectric layer is formed and a second region different from the first region and in which an epitaxial pattern is formed, and the steps of forming the second spacer material layer and the third spacer material layer include the following. A first mask layer for defining the epitaxial pattern is formed on the substrate before forming the epitaxial pattern. The first mask layer covers the gate dielectric layer on the first region, the first spacer layer, and the gate electrode. A second mask layer is formed on the first mask layer and the epitaxial pattern after forming the epitaxial pattern. The second mask layer is patterned to form a third spacer material layer. A portion of the first mask layer not covered by the third spacer material layer is removed to form the second spacer material layer.

In some embodiments, a thickness of the first portion of the second spacer layer or the third spacer layer is approximately equal to a thickness of the second portion of the second spacer layer or the third spacer layer.

In some embodiments, the second gate spacer includes a fourth spacer layer formed on the third spacer layer and a fifth spacer layer formed on the fourth spacer layer. The fourth spacer layer includes a first portion extending along the sidewall of the gate electrode and a second portion extending in the direction from the gate electrode to the source/drain.

In some embodiments, a thickness of the first portion of the fourth spacer layer is approximately equal to a thickness of the second portion of the fourth spacer layer, and the fifth spacer layer includes a portion with a thickness changing along a direction perpendicular to a surface of the substrate.

In some embodiments, a bottom surface of the fifth spacer layer is formed at a level higher than a top surface of the gate dielectric layer.

In some embodiments, a side surface of the fifth spacer layer away from the gate electrode includes a first profile and a second profile different from the first profile, and relative to a surface of the substrate, the first profile is positioned above the second profile and has a slope less than a slope of the second profile.

In some embodiments, materials of the first spacer layer, the second spacer layer, and the fifth spacer layer include nitride, and materials of the third spacer layer and the fourth spacer layer include oxide.

Based on the above, in the semiconductor structure and the method for forming the same, the second spacer layer and the third spacer layer each include an extension portion extending in the direction from the gate electrode to the source/drain. Therefore, leakage current caused by hot carrier injection (HCI) can be reduced by increasing the width of the gate spacer.

### BRIEF DESCRIPTION OF THE DRAWINGS

FIG. 1 to FIG. 10 are schematic cross-sectional views of a method for forming a semiconductor structure according to an embodiment of the disclosure.

### DESCRIPTION OF THE EMBODIMENTS

The disclosure will be described more fully with reference to the drawings of the embodiments. However, the disclosure may also be embodied in various forms and should not be limited to the embodiments described herein. Thicknesses of layers and region in the drawings are exaggerated for clarity. The same or similar reference numerals indicate the same or similar elements, which will not be repeated one by one in the following paragraphs.

It will be understood that when an element is referred to as being “on” or “connected to” another element, the element may be directly on the other element or connected to the other element, or there may be an intervening element. When an element is referred to as being “directly on” or “directly connected to” another element, there is no intervening element. As used herein, “connection” may refer to physical and/or electrical connection, and “electrical connection” or “coupling” may be that there is another element between two elements.

“About”, “approximately”, or “substantially” used herein includes the mentioned value and the average value within an acceptable deviation range from the specific value that persons with ordinary skill in the art can determine, taking into account the measurement in discussion and the specific amount of error (that is, limitations of a measurement system) associated with the measurement. For example, “about” may mean within one or more standard deviations or within ±30%, ±20%, ±10%, or ±5% of the stated value. Furthermore, an acceptable deviation range or standard deviation may be selected for “about”, “approximately”, or “substantially” used herein according to optical properties, etching properties, or other properties, and one standard deviation does not need to be applied to all properties.

Terminology used herein is used only to describe illustrative embodiments and does not limit the disclosure. In such cases, the singular form includes the plural form unless the context dictates otherwise.

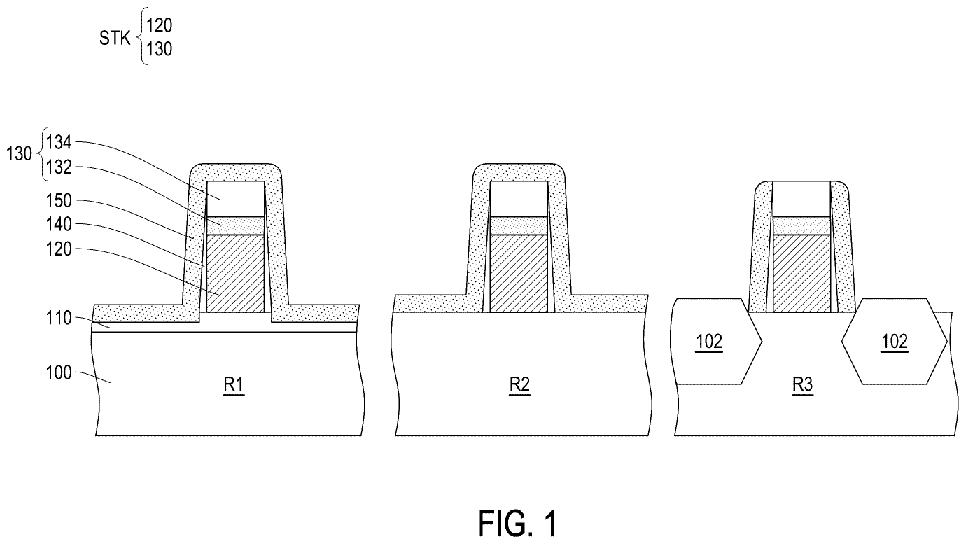

FIG. 1 to FIG. 10 are schematic cross-sectional views of a method for forming a semiconductor structure according to an embodiment of the disclosure.

First, please refer to FIG. 1. A substrate 100 is provided. The substrate 100 may include a first region R1, a second region R2, and a third region R3. In some embodiments, the first region R1 may be a region in which a medium-voltage semiconductor element is disposed. In some embodiments, the second region R2 and the third region R3 may respectively be a region in which a low-voltage semiconductor element is disposed. An operating voltage (for example, 8V) of the medium-voltage semiconductor element may be greater than an operating voltage (for example, 0.9V) of the low-voltage semiconductor element.

The substrate 100 may include a semiconductor substrate or a semiconductor on insulator (SOI) substrate. The semiconductor material in the semiconductor substrate or the SOI substrate may include an element semiconductor, an alloy semiconductor, or a compound semiconductor. For example, the elemental semiconductor may include Si or Ge. The alloy semiconductor may include SiGe, SiGeC, etc. The compound semiconductor may include SiC, an III-V semiconductor material, or an II-VI semiconductor material. The III-V semiconductor material may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor material may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type that is complementary to the first conductivity type. For example, the first conductivity type may be N type, and the second conductivity type may be P type. In some embodiments, the second region R2 and the third region R3 of the substrate 100 may be respectively doped with dopants of different conductivity types. For example, the substrate 100 may be doped with the dopant of the first conductivity type (for example, N type) in the second region R2, and the substrate 100 may be doped with the dopant of the second conductivity type (for example, P type) in the third region R3. In some embodiments, the first region R1, the second region R2, and the third region R3 of the substrate 100 may be defined by element isolation structures (not shown), but not limited thereto.

Next, a gate dielectric material layer 110 is formed on the first region R1 of the substrate 100. In some embodiments, the gate dielectric material layer 110 may include a material used for a gate dielectric layer such as silicon oxide. In some embodiments, the gate dielectric material layer 110 may be formed by the following steps. First, a portion of the substrate 100 is removed to form a groove. Then, the gate dielectric material layer 110 is formed by processes such as thermal oxidation and/or deposition. As shown in FIG. 1, a top surface of the gate dielectric material layer 110 formed at the groove may be lower than a top surface of the substrate 100 at other regions (for example, the second region R2 or the third region R3).

Then, a gate electrode 120 is formed on the gate dielectric material layer 110. In some embodiments, a cap layer 130 including the first material layer 132 and the second material layer 134 is also formed on the gate electrode 120. In some embodiments, the material of the first material layer 132 may be different from the material of the second material layer 134. For example, the first material layer 132 may include nitride, and the second material layer 134 may include oxide. In some embodiments, a stack structure STK including the gate electrode 120 and the cap layer 130 may be formed on the second region R2 and the third region R3 of the substrate 100.

Then, first spacer layers 140 are formed on two opposite sidewalls of the stack structure STK. In some embodiments, the first spacer layer 140 may include nitride such as SiCN. In some embodiments, the gate dielectric material layer 110 includes a first portion below the gate electrode 120 and the first spacer layer 140 and a second portion different from the first portion, wherein the thickness of the first portion is greater than the thickness of the second portion.

Afterwards, a first mask layer 150 covering the gate dielectric material layer 110, the first spacer layer 140, and the stack structure STK is formed above the substrate 100. In some embodiments, in the third region R3 of the substrate 100, the first mask layer 150 may define a region for forming an epitaxial pattern 102 in the third region R3 of the substrate 100 together with the stack structure STK and the first spacer layer 140. Then, an epitaxy process may be performed on the region to form the epitaxial pattern 102 as shown in FIG. 1. In some embodiments, the epitaxial pattern 102 may include a material such as silicon germanium (SiGe). In some embodiments, the first mask layer 150 may include nitride such as silicon nitride (SiN).

In some embodiments, as shown in FIG. 1, the substrate 100 may include the first region R1 on which the gate dielectric material layer 110 is formed, the third region R3 different from the first region R1 and in which the epitaxial pattern 102 is formed, and the second region R2 different from the first region R1 and the third region R3. In the embodiment, the first region R1 of the substrate 100 may be a region in which the medium-voltage semiconductor element is formed, the second region R2 of the substrate 100 may be a region in which the low-voltage semiconductor element is formed and doped with the dopant of the first conductivity type (for example, N type), and the third region R3 of the substrate 100 may be a region in which the low-voltage semiconductor element is formed and doped with the dopant of the second conductivity type (for example, P type).

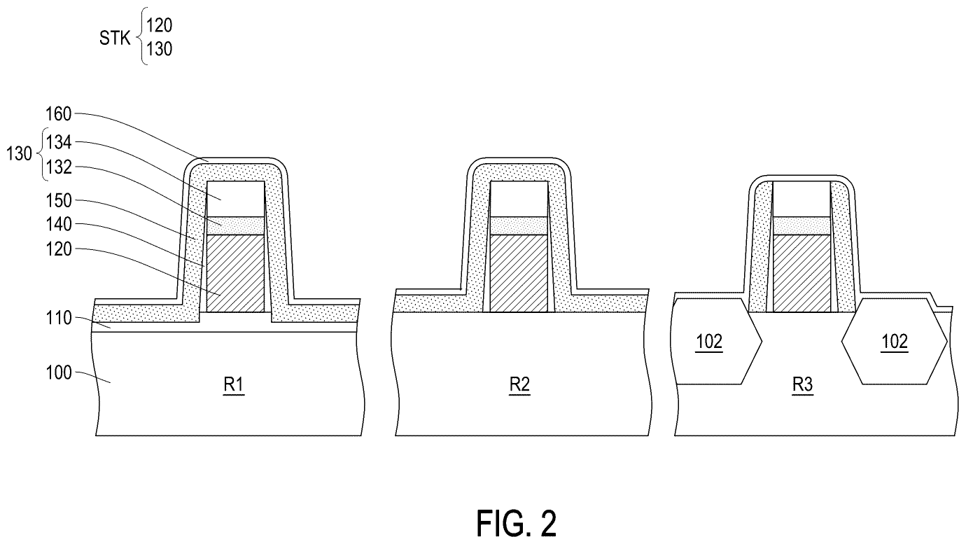

Next, please refer to FIG. 1 and FIG. 2. After forming the epitaxial pattern 102, a second mask layer 160 is formed on the first mask layer 150 and the epitaxial pattern 102. The material of the second mask layer 160 is different from the material of the first mask layer 150. In some embodiments, the second mask layer 160 may include oxide such as silicon oxide. In some embodiments, the thickness of the second mask layer 160 may be approximately 50 Å, but not limited thereto.

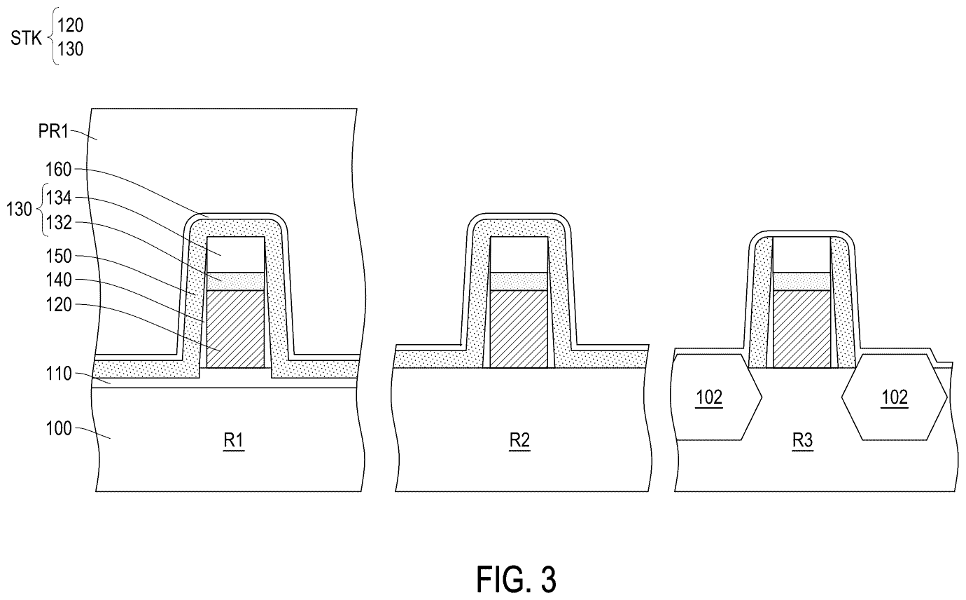

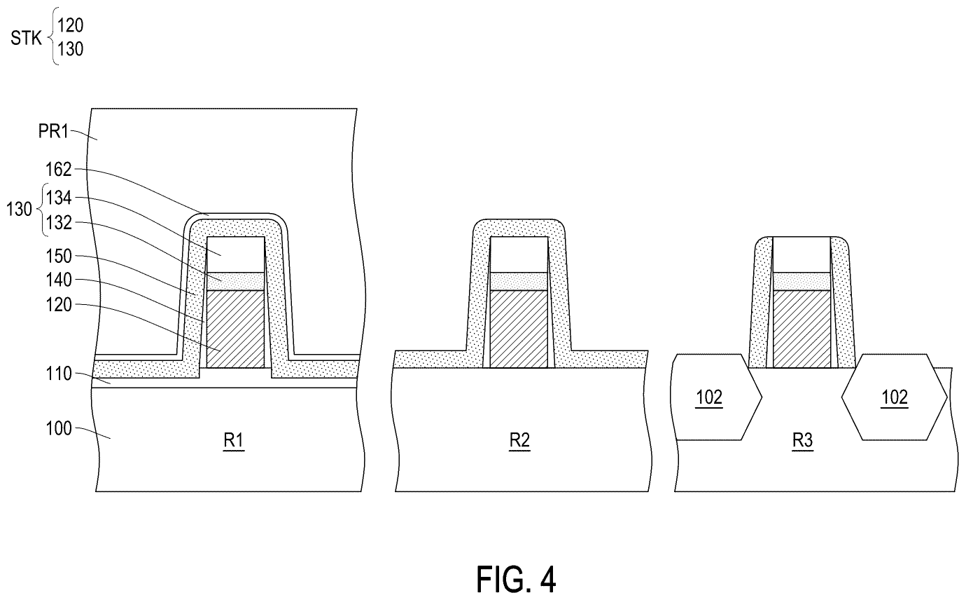

Then, the second mask layer 160 is patterned to form a third spacer material layer 162. In some embodiments, the third spacer material layer 162 may be formed by the following steps. First, please refer to FIG. 3. A mask pattern PR1 is formed on the first region R1 of the substrate 100 to cover the second mask layer 160 in the first region R1 and expose the second mask layer 160 in the second region R2 and the third region R3. In some embodiments, the mask pattern PR1 may be a photoresist pattern. Next, please refer to FIG. 4. The second mask layer 160 exposed by the mask pattern PR1 is removed to form the third spacer material layer 162 in the first region R1. In some embodiments, wet etching may be adopted to remove the second mask layer 160 exposed by the mask pattern PR1.

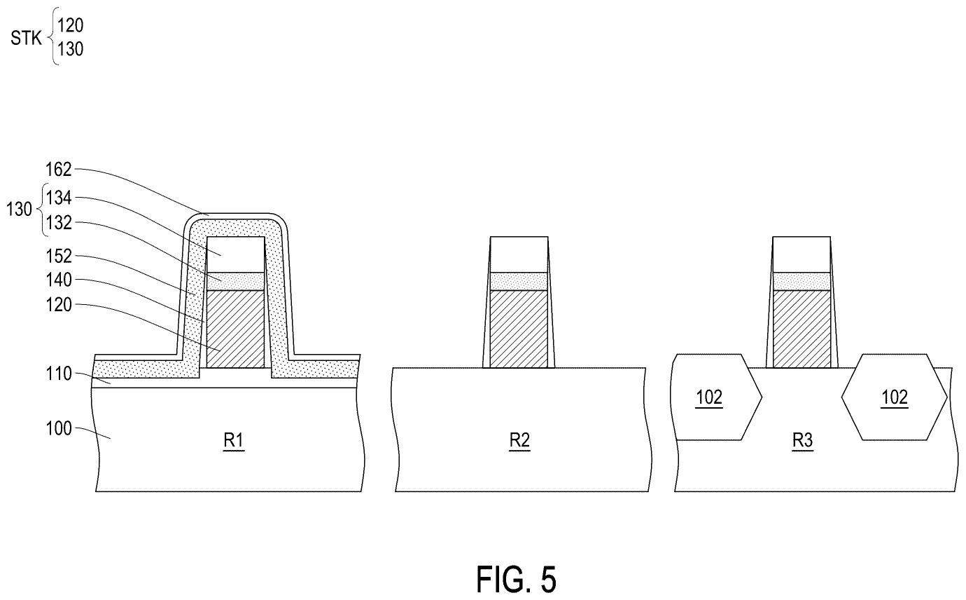

After that, please refer to FIG. 4 and FIG. 5. The mask pattern PR1 is removed and a portion of the first mask layer 150 not covered by the third spacer material layer 162 is removed to form the second spacer material layer 152. In some embodiments, wet etching through an etching solution such as phosphoric acid (H₃PO₄) may be adopted to remove the portion of the first mask layer 150 not covered by the third spacer material layer 162.

As shown in FIG. 5, the second spacer material layer 152 is formed above the substrate 100 to cover the gate dielectric material layer 110, the first spacer layer 140, and the stack structure STK, and the third spacer material layer 162 is formed on the second spacer material layer 152.

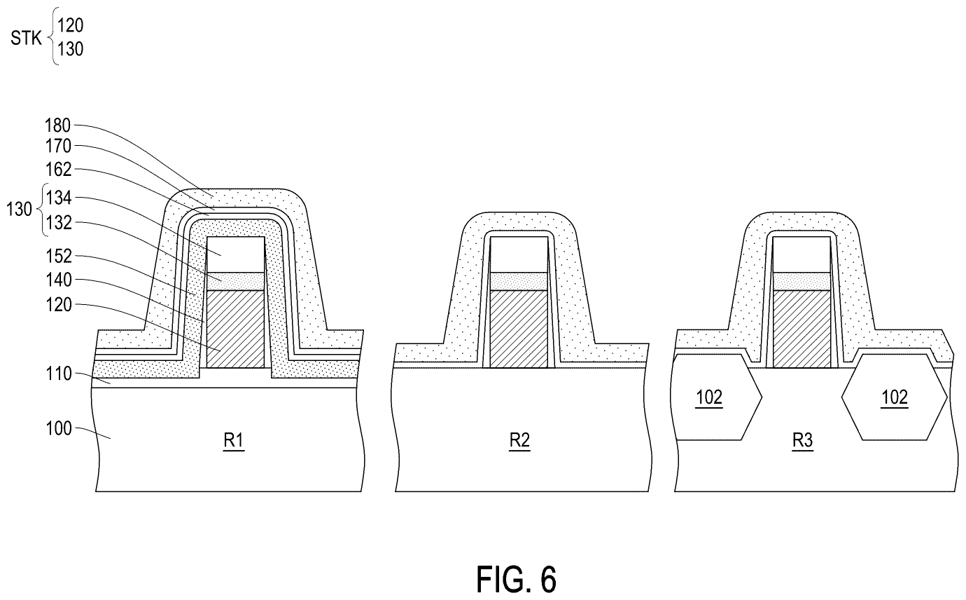

Next, please refer to FIG. 5 and FIG. 6. A fourth spacer material layer 170 and a fifth spacer material layer 180 are sequentially formed on the substrate 100 to form a second gate spacer material layer including the fourth spacer material layer 170 and the fifth spacer material layer 180 on the third spacer material layer 162 in the first region R1, the second gate spacer material layer including the fourth spacer material layer 170 and the fifth spacer material layer 180 on the substrate 100, the first spacer layer 140, and the stack structure STK in the second region R2, and the second gate spacer material layer including the fourth spacer material layer 170 and the fifth spacer material layer 180 on the substrate 100, the epitaxial pattern 102, the first spacer layer 140, and the stack structure STK in the third region R3. The material of the fourth spacer material layer 170 is different from the material of the fifth spacer material layer 180. For example, the fourth spacer material layer 170 may include oxide such as silicon oxide, and the fifth spacer material layer 180 may include nitride such as silicon nitride.

Then, as shown in FIG. 6 to FIG. 10, a portion of the fourth spacer material layer 170 and the fifth spacer material layer 180 is removed (such as removing a portion located above a top surface of the stack structure STK and above the top surface of the substrate 100) to form second gate spacers SP2 above opposite sidewalls of the stack structure STK. The second gate spacer SP2 may be formed to include a fourth spacer layer 172 and a fifth spacer layer 182.

Then, a portion of the third spacer material layer 162 and the second spacer material layer 152 is removed (such as removing a portion above the top surface of the stack structure STK and above the top surface of the substrate 100) to respectively form a third spacer layer 164 and a second spacer layer 154 on the first spacer layer 140, so that a first gate spacer SP1 including the first spacer layer 140, the second spacer layer 154, and the third spacer layer 164 may be formed.

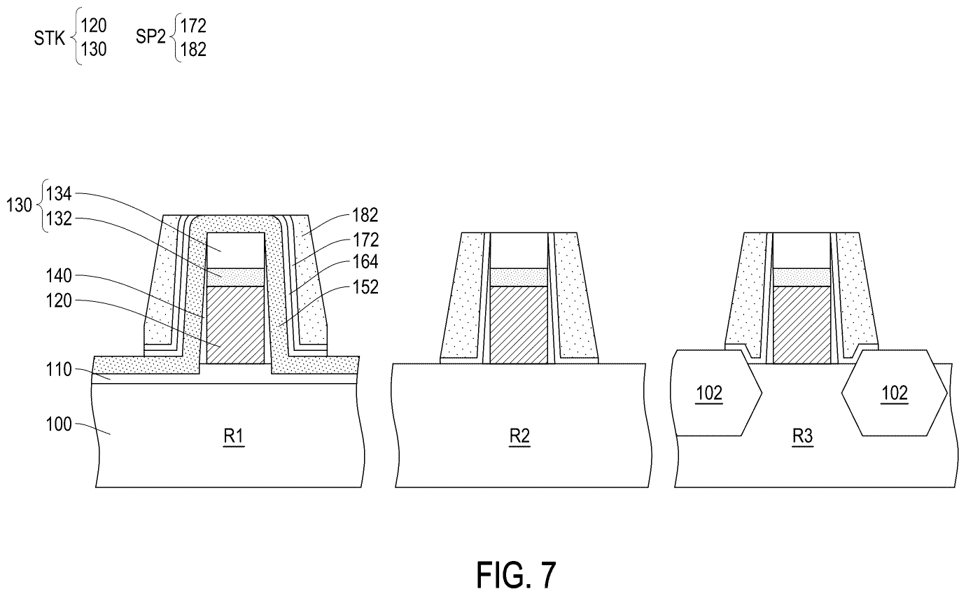

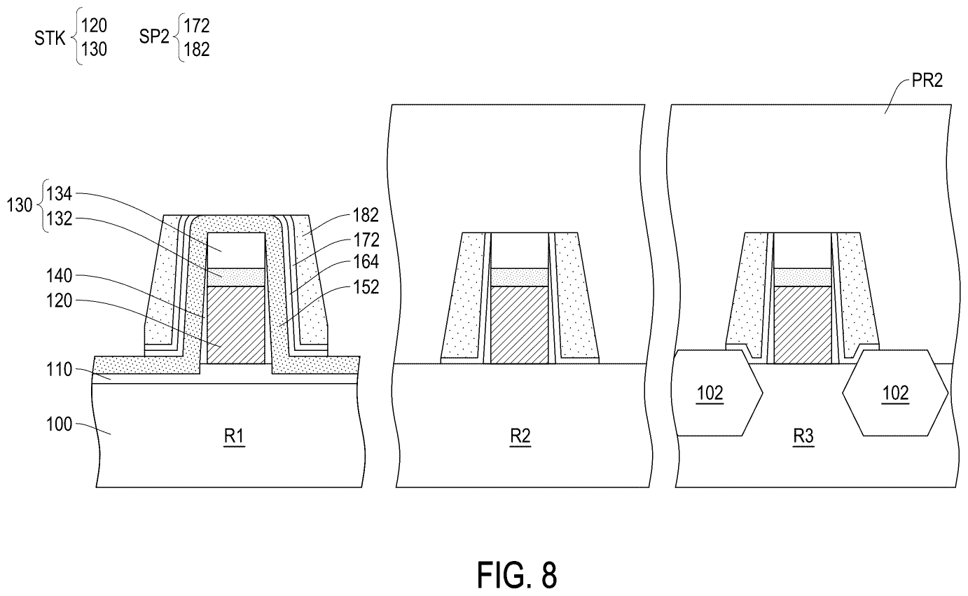

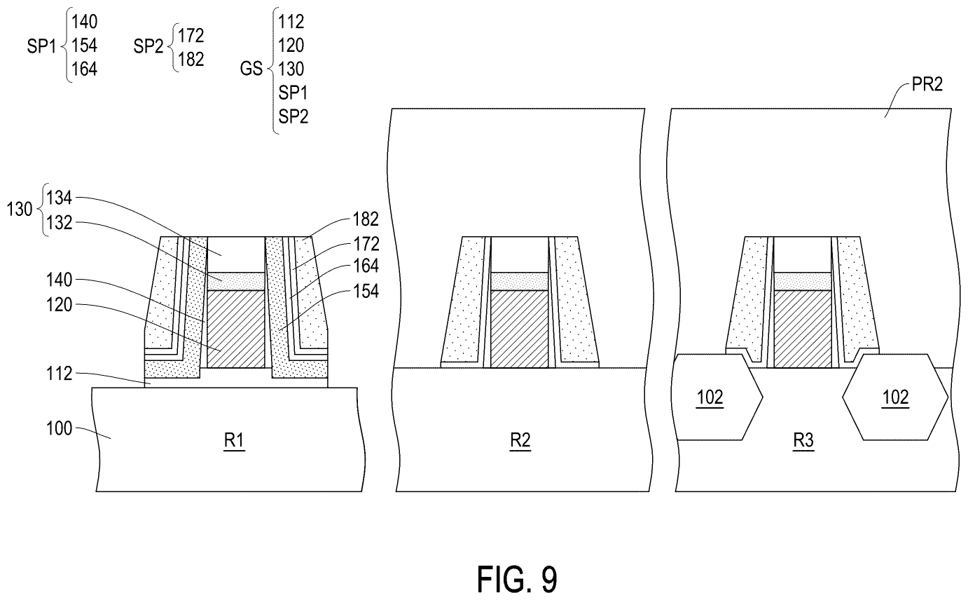

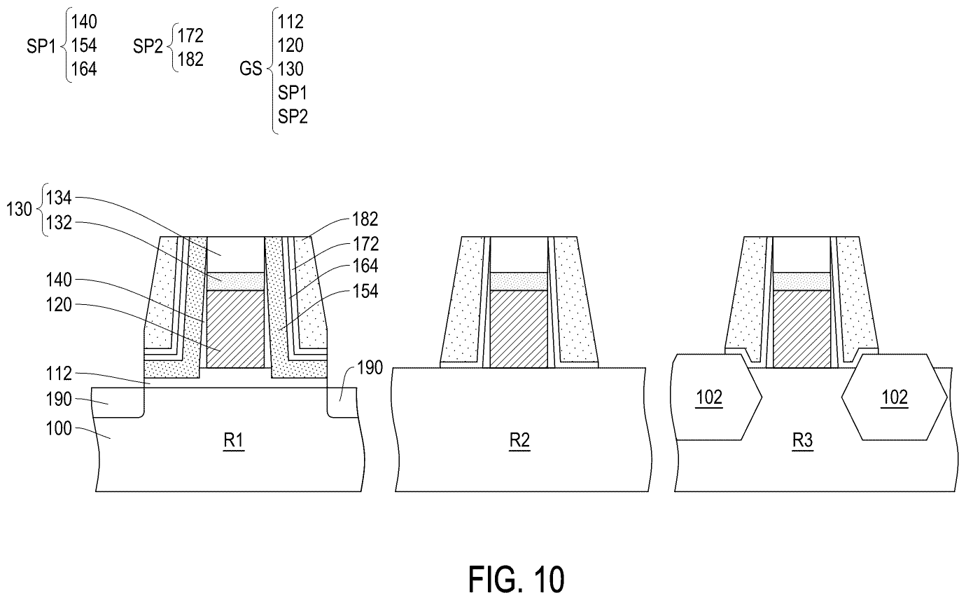

In some embodiments, as shown in FIG. 6 and FIG. 7, in the step of forming the second gate spacer SP2, a portion of the third spacer material layer 162 located above the top surface of the stack structure STK and above the top surface of the substrate 100 is also removed to form the third spacer layer 164. In some embodiments, the second spacer layer 154 may be formed by the following steps. First, please refer to FIG. 8. A mask pattern PR2 covering the second region R2 and the third region R3 and exposing the first region R1 is formed. In some embodiments, the mask pattern PR2 may be a photoresist pattern. Next, please refer to FIG. 8 and FIG. 9. Dry etching may be adopted to remove a portion of the second spacer material layer 152 exposed by the second gate spacer SP2 and the third spacer layer 164 below the second gate spacer SP2 and a portion of the gate dielectric material layer 110 below the portion of the second spacer material layer 152 to form the second spacer layer 154 and a gate dielectric layer 112. In some embodiments, the dry etching may be used in conjunction with, for example, some necessary mask patterns, but not limited thereto. Then, please refer to FIG. 9 and FIG. 10. After forming the second spacer layer 154 and the gate dielectric layer 112, the mask pattern PR2 is removed. After the above steps, a gate structure GS including the gate dielectric layer 112, the gate electrode 120, the cap layer 130, the first gate spacer SP1, and the second gate spacer SP2 may be formed in the first region R1.

Afterwards, please refer to FIG. 10. A source/drain 190 is formed in the substrate 100 at opposite sides of the gate structure GS. In the embodiment, as shown in FIG. 10, the second spacer layer 154 and the third spacer layer 164 in the gate structure GS each include a first portion extending along a sidewall of the gate electrode 120 and a second portion extending in a direction from the gate electrode 120 to the source/drain 190, so that the gate structure GS can have wider gate spacers (the first gate spacer SP1 and the second gate spacer SP2) to prevent leakage current caused by hot carrier injection (HCI).

In some embodiments, as shown in FIG. 10, the thickness of the first portion of the second spacer layer 154 or the third spacer layer 164 may be formed to be approximately equal to the thickness of the second portion of the second spacer layer 154 or the third spacer layer 164.

The second gate spacer SP2 may be formed to include the fourth spacer layer 172 and the fifth spacer layer 182, wherein the fourth spacer layer 172 is formed on the third spacer layer 164, and the fifth spacer layer 182 is formed on the fourth spacer layer 172. In some embodiments, as shown in FIG. 10, the fourth spacer layer 172 may include a first portion extending along the sidewall of the gate electrode 120 and a second portion extending in the direction from the gate electrode 120 to the source/drain 190. In some embodiments, the thickness of the first portion of the fourth spacer layer 172 may be formed to be approximately equal to the thickness of the second portion of the fourth spacer layer 172, and the fifth spacer layer 182 may be formed to include a portion with a thickness changing along a direction perpendicular to a surface of the substrate 100.

In some embodiments, a bottom surface of the fifth spacer layer 182 may be formed at a level higher than a top surface of the gate dielectric layer 112. In some embodiments, a side surface of the fifth spacer layer 182 away from the gate electrode 120 may be formed to include a first profile and a second profile different from the first profile, wherein relative to the surface of the substrate 100, the first profile is positioned above the second profile and has a slope less than the slope of the second profile.

Hereinafter, a semiconductor structure according to an embodiment of the disclosure will be illustrated with reference to FIG. 10. The semiconductor structure of the embodiment may be formed by the method described above, but not limited thereto.

Please refer to FIG. 10. The semiconductor structure includes the substrate 100, the gate structure GS disposed on the substrate 100, and the source/drain 190 disposed in the substrate 100 at the opposite sides of the gate structure GS. The gate structure GS includes the gate dielectric layer 112 disposed on the substrate 100, the gate electrode 120 disposed on the gate dielectric layer 112, the first gate spacers SP1 disposed on opposite sidewalls of the gate electrode 120, and the second gate spacers SP2 disposed on the first gate spacers SP1. The first gate spacers SP1 each include the first spacer layer 140 on the sidewall of the gate electrode 120, the second spacer layer 154 on the first spacer layer 140, and the third spacer layer 164 on the second spacer layer 154. The second spacer layer 154 and the third spacer layer 164 each include the first portion extending along the sidewall of the gate electrode 120 and the second portion extending in the direction from the gate electrode 120 to the source/drain 190.

In some embodiments, the thickness of the first portion of the second spacer layer 154 may be approximately equal to the thickness of the second portion of the second spacer layer 154. In some embodiments, the thickness of the first portion of the third spacer layer 164 may be approximately equal to the thickness of the second portion of the third spacer layer 164.

In some embodiments, the gate dielectric layer 112 may include a first portion below the gate electrode 120 and a second portion below the second portion of each of the second spacer layer 154 and the third spacer layer 164. In some embodiments, the thickness of the first portion of the gate dielectric layer 112 may be greater than the thickness of the second portion of the gate dielectric layer 112.

In some embodiments, the second gate spacer SP2 may include the fourth spacer layer 172 disposed on the third spacer layer 164 and the fifth spacer layer 182 disposed on the fourth spacer layer 172. The fourth spacer layer 172 may include the first portion extending along the sidewall of the gate electrode 120 and the second portion extending in the direction from the gate electrode 120 to the source/drain 190. In some embodiments, the thickness of the first portion of the fourth spacer layer 172 may be approximately equal to the thickness of the second portion of the fourth spacer layer 172, and the fifth spacer layer 182 may include the portion with the thickness changing along the direction perpendicular to the surface of the substrate 100.

In some embodiments, the bottom surface of the fifth spacer layer 182 may be disposed at a level higher than the top surface of the gate dielectric layer 112. In some embodiments, the side surface of the fifth spacer layer 182 away from the gate electrode 120 includes the first profile and the second profile different from the first profile. In some embodiments, relative to the surface of the substrate 100, the first profile is positioned above the second profile and has the slope less than the slope of the second profile.

In some embodiments, the materials of the first spacer layer 140, the second spacer layer 154, and the fifth spacer layer 182 include nitride, and the materials of the third spacer layer 164 and the fourth spacer layer 172 include oxide. In some embodiments, the material of the first spacer layer 140 may be different from the materials of the second spacer layer 154 and the fifth spacer layer 182. For example, the first spacer layer 140 may include SiCN, and the second spacer layer 154 and the fifth spacer layer 182 may include SiN.

In summary, in the semiconductor structure and the method for forming the same according to the above embodiments, in the first gate spacer of the gate structure, the second spacer layer and the third spacer layer each include an extension portion extending in the direction from the gate electrode to the source/drain, and the extension portion can further increase the width of the gate spacer, which can reduce leakage current caused by hot carrier injection (HCI).

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor structure, comprising:
a substrate;
a gate structure, disposed on the substrate; and
a source/drain, disposed in the substrate at opposite sides of the gate structure,
wherein the gate structure comprises:
a gate dielectric layer, disposed on the substrate;
a gate electrode, disposed on the gate dielectric layer;
first gate spacers, disposed on opposite sidewalls of the gate electrode and each comprising a first spacer layer on the sidewall of the gate electrode, a second spacer layer on the first spacer layer, and a third spacer layer on the second spacer layer; and
second gate spacers, disposed on the first gate spacers,
wherein the second spacer layer and the third spacer layer each comprise a first portion extending along the sidewall of the gate electrode and a second portion extending in a direction from the gate electrode to the source/drain.

2. The semiconductor structure according to claim 1, wherein a thickness of the first portion of the second spacer layer is approximately equal to a thickness of the second portion of the second spacer layer.

3. The semiconductor structure according to claim 1, wherein a thickness of the first portion of the third spacer layer is approximately equal to a thickness of the second portion of the third spacer layer.

4. The semiconductor structure according to claim 1, wherein the gate dielectric layer comprises a first portion under the gate electrode and a second portion below the second portion of each of the second spacer layer and the third spacer layer.

5. The semiconductor structure according to claim 4, wherein a thickness of the first portion of the gate dielectric layer is greater than a thickness of the second portion of the gate dielectric layer.

6. The semiconductor structure according to claim 1, wherein the second gate spacer comprises:
a fourth spacer layer, disposed on the third spacer layer; and
a fifth spacer layer, disposed on the fourth spacer layer,
wherein the fourth spacer layer comprises a first portion extending along the sidewall of the gate electrode and a second portion extending in the direction from the gate electrode to the source/drain.

7. The semiconductor structure according to claim 6, wherein a thickness of the first portion of the fourth spacer layer is approximately equal to a thickness of the second portion of the fourth spacer layer, and the fifth spacer layer comprises a portion with a thickness changing along a direction perpendicular to a surface of the substrate.

8. The semiconductor structure according to claim 6, wherein a bottom surface of the fifth spacer layer is disposed at a level higher than a top surface of the gate dielectric layer.

9. The semiconductor structure according to claim 6, wherein a side surface of the fifth spacer layer away from the gate electrode comprises a first profile and a second profile different from the first profile.

10. The semiconductor structure according to claim 9, wherein relative to a surface of the substrate, the first profile is positioned above the second profile and has a slope less than a slope of the second profile.

11. The semiconductor structure according to claim 6, wherein materials of the first spacer layer, the second spacer layer, and the fifth spacer layer comprise nitride, and materials of the third spacer layer and the fourth spacer layer comprise oxide.

12. The semiconductor structure according to claim 11, wherein the material of the first spacer layer is different from the materials of the second spacer layer and the fifth spacer layer.

13. A method for forming a semiconductor structure, comprising:
forming a gate dielectric layer on a substrate;
forming a gate electrode on the gate dielectric layer;
forming first spacer layers on opposite sidewalls of the gate electrode;
forming a second spacer material layer covering the gate dielectric layer, the first spacer layer, and the gate electrode above the substrate;
forming a third spacer material layer on the second spacer material layer;
forming a second gate spacer material layer on the third spacer material layer;
removing a portion of the second gate spacer material layer to form second gate spacers above the opposite sidewalls of the gate electrode;
removing a portion of the third spacer material layer and the second spacer material layer to respectively form a third spacer layer and a second spacer layer on the first spacer layer; and
forming a source/drain in the substrate at opposite sides of the gate electrode,
wherein the second spacer layer and the third spacer layer each comprise a first portion extending along the sidewall of the gate electrode and a second portion extending in a direction from the gate electrode to the source/drain.

14. The method according to claim 13, wherein the substrate comprises a first region on which the gate dielectric layer is formed and a second region different from the first region and in which an epitaxial pattern is formed, and the steps of forming the second spacer material layer and the third spacer material layer comprise:
forming a first mask layer for defining the epitaxial pattern on the substrate before forming the epitaxial pattern, wherein the first mask layer covers the gate dielectric layer on the first region, the first spacer layer, and the gate electrode;
forming a second mask layer on the first mask layer and the epitaxial pattern after forming the epitaxial pattern;
patterning the second mask layer to form a third spacer material layer; and
removing a portion of the first mask layer not covered by the third spacer material layer to form the second spacer material layer.

15. The method according to claim 13, wherein a thickness of the first portion of the second spacer layer or the third spacer layer is approximately equal to a thickness of the second portion of the second spacer layer or the third spacer layer.

16. The method according to claim 13, wherein the second gate spacer comprises:
a fourth spacer layer, formed on the third spacer layer; and
a fifth spacer layer, formed on the fourth spacer layer,
wherein the fourth spacer layer comprises a first portion extending along the sidewall of the gate electrode and a second portion extending in the direction from the gate electrode to the source/drain.

17. The method according to claim 16, wherein a thickness of the first portion of the fourth spacer layer is approximately equal to a thickness of the second portion of the fourth spacer layer, and the fifth spacer layer comprises a portion with a thickness changing along a direction perpendicular to a surface of the substrate.

18. The method according to claim 16, wherein a bottom surface of the fifth spacer layer is formed at a level higher than a top surface of the gate dielectric layer.

19. The method according to claim 16, wherein a side surface of the fifth spacer layer away from the gate electrode comprises a first profile and a second profile different from the first profile, and relative to a surface of the substrate, the first profile is positioned above the second profile and has a slope less than a slope of the second profile.

20. The method according to claim 16, wherein materials of the first spacer layer, the second spacer layer, and the fifth spacer layer comprise nitride, and materials of the third spacer layer and the fourth spacer layer comprise oxide.
